(19) United States
(12) Patent Application Publication
(10) Pub. No.: US 2005/0095513 A1
(43) Pub. Date: May 5, 2005

(54) Photomask

(75) Inventors: Teruyoshi Yao, Kawasaki (JP); Satoru Asai, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/006,688

(22) Filed: Dec. 8, 2004

Related U.S. Application Data
(63) Continuation of application No. PCT/JP03/01772, filed on Feb. 19, 2003.

(30) Foreign Application Priority Data
Jul. 31, 2002 (JP) 2002-223967

(51) Int. Cl. G03F 9/00; G03C 5/00

(52) U.S. Cl. 430/5; 430/394

(57) ABSTRACT

Dummy patterns serving as sub-patterns are formed in virtual regions (2, 3). The numerical apertures of when only main patterns are formed in the virtual regions (2, 3) are 60% and 90%, respectively. The dummy pattern in the virtual region (2) is a light-shielding pattern of a rectangle having a side of 0.15 μm and the dummy pattern in the virtual region 3 is a light-shielding pattern of a rectangle having a side of 0.2 μm. The numerical apertures of the virtual regions (2, 3) are both set to 30%. When exposure using such a photomask is conducted, the amount of light produced by local flare is almost uniform at any point in the area where exposure light is applied on a photosensitive body. As a result, variation of the line width, even if caused, is uniform over the photomask.

### TECHNICAL FIELD

The present invention relates to a photomask used in a photolithography conducted when manufacturing a semiconductor device and so forth, a designing method of the same, and a semiconductor manufacturing method using the same.

### BACKGROUND ART

When manufacturing a semiconductor device and so forth, a variety of patterns formed on a photomask are transferred to a photoresist formed on a substrate by photolithography. After the transferring, the photoresist is developed, and with the use of the patterns on the photoresist as a mask, a processing of a wiring layer or the like is conducted. In such a photolithography, a projecting exposure apparatus of a dioptric system or catadioptric system is used.

However, in such a lithography, an optical path different from a design is formed due to reflection, scattering, or variety of refraction indices of lens materials on a surface of or inside a lens of an illumination optical system, a mask, a projection lens, or so forth as a cause, generating a light via the optical path. Such a phenomenon is referred to as a flare. When the flare is caused, the patterns transferred to the photoresist vary in feature and line width.

Therefore, conventionally, the flare has been addressed and reduced by approaches to coat the surface of the lens, to improve flatness of the surface of the lens, or the like.

However, in addition to the flare, recently, a phenomenon called “local flare” is viewed as a problem. The local flare is caused by aberration of an exposure apparatus. When the local flare is caused, similarly to the flare, variation in the line width or the like is caused. The local flare caused by one pattern in the mask affects in the range of about 50 μm from the pattern. Note that the affected range may vary depending on a generation or an exposure wave length both of the exposure apparatus, in the future. In addition, the local flare affects variously depending on a numerical aperture in the vicinity of the pattern, so that the local flare affects differently depending on positions on the photomask. Accordingly, in the resist pattern, the line width varies at various levels depending on the position. It is therefore extremely difficult to modify the pattern on the photomask in view of the influence of the local flare.

Recently, the semiconductor device is increasingly improved in miniaturization and integration, and along with such improvements, reduction in wavelength is in progress for the exposure light used in the projecting exposure apparatus. Specifically, an exposure light of a wavelength of 193 nm is in use, whereas, due to specificity of the lens when responding to such a wavelength, light coverage differs in accordance with an opening area in the vicinity of one pattern, in which a flare caused locally depending on an exposure pattern is gradually regarded as a problem. Such a flare is called “local flare”, and causes, as a main cause, a contingent variation in the feature or the line width of the pattern transferred. The previously-described aberration of the exposure apparatus is due to the specificity of the lens material.

### SUMMARY OF THE INVENTION

The present invention has been made in consideration of the above-described problem, and an object thereof is to provide a photomask capable of restraining a difference in variation amount of a line width caused by a local flare, a designing method of the same, and a semiconductor device manufacturing method using the same.

After due diligent efforts to bring a solution to the problem, the present inventors have devised embodiments as will be described below.

A first photomask according to the present invention is intended for a photomask having a main pattern which is to be transferred to a photosensitive body formed thereon and used for manufacturing a semiconductor device. The photomask is characterized in that a plurality of sub-patterns are formed optional to be transferred or not to the photosensitive body, and when an irradiation region to be applied at least exposure light is sectioned into a plurality of virtual regions having a certain feature, numerical apertures are substantially uniform over the plural virtual regions.

A second photomask according to the present invention is characterized in that, in contrast to the first photomask, of the plural virtual regions, those virtual regions exhibiting a lower numerical aperture in aggregate for every pattern except the sub-pattern have lesser amount of reduction in the numerical aperture due to the formation of the sub-patterns.

Further, a first designing method of a photomask according to the present invention is intended for a designing method of a photomask having a main pattern which is to be transferred to a photosensitive body formed thereon and used for manufacturing a semiconductor device. In this designing method, first, a main pattern is determined based on a circuitry of the semiconductor device. Next, an irradiation region to be applied at least exposure light is sectioned into a plurality of virtual regions of a certain optional feature and an aggregate numerical aperture is calculated for the patterns determined at that time for each virtual region. After that, a plurality of sub-patterns being optional to be transferred or not to the photosensitive body are determined. The designing method of the photomask is characterized in that, in the step of determining a plurality of sub-patterns, the numerical apertures are made to be substantially uniform over the plural virtual regions.

A second designing method of a photomask according to the present invention is, in contrast to the first designing method of a photomask, characterized in that, in the step of determining a plurality of sub-patterns, those virtual regions exhibiting a lower numerical aperture in aggregate for every pattern except the sub-pattern have lesser amount of reduction in the numerical aperture due to formation of the sub-patterns.

According to these embodiments of the present invention, an influence of a local flare comes to be substantially uniform over an entire photomask, so that variations in line width or the like of patterns formed on a photosensitive body by a transfer come to be uniform in similar fashion. Such a uniform variation in size allows modification with ease for example by adjusting output energy of an exposure apparatus or the like, so that a desired pattern can be transferred to a photosensitive body easily.

### BRIEF DESCRIPTION OF THE DRAWINGS

FIG. 1 is a schematic view showing a positional relationship on a photomask among a region A, a region B, and a region C;

FIG. 2A to FIG. 2C are schematic views showing a quantifying method of a local flare;

FIG. 3 is a graphic chart obtained from the method shown in FIG. 2A to FIG. 2C;

FIG. 4 is a schematic view showing a fundamental principle of the present invention;

FIG. 5A to FIG. 5D are schematic views showing a photomask according to a first embodiment of the present invention;

FIG. 6A to FIG. 6D are schematic views showing a photomask according to a second embodiment of the present invention;

FIG. 7A to FIG. 7D are schematic views showing a photomask according to a third embodiment of the present invention;

FIG. 8A to FIG. 8D are schematic views showing a photomask according to a fourth embodiment of the present invention; and

FIG. 9A to FIG. 9D are schematic views showing a photomask reversing positive/negative types of the first embodiment.

### DETAILED DESCRIPTION OF THE PREFERRED EMBODIMENTS

### Basic Gist of the Present Invention

First, a basic gist of the present invention will be described with reference to the attached drawings. FIG. 1 is a schematic view showing a positional relationship on a photomask among a region A, a region B, and a region C.

In FIG. 1, it is assumed that an arbitrary region A and arbitrary regions B and C be distant from each other within a range of about 20 μm. When a light is applied to such a photomask, a flare caused by the light transmitting the regions B and C affects a pattern to be formed on a photosensitive body (body to be transferred) such as a photoresist by a transfer of a pattern formed on the region A. As a result, when a line pattern is formed in the region A, a line width thereof varies.

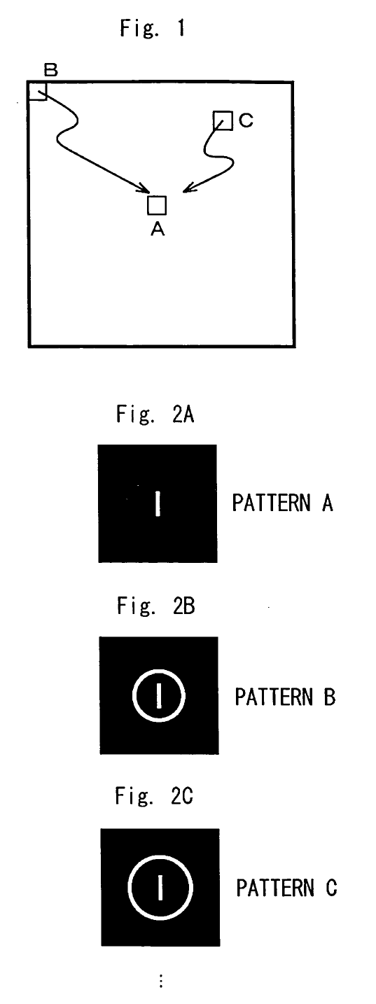

Here, a relation between a distance between a pattern affected by a local flare and a pattern affecting and an affecting level of the local flare will be described. As to the relation, the present inventors have found that the affecting level of the local flare increases as the distance between the two patterns is shortened. FIG. 2A to FIG. 2C are schematic views showing a quantifying method of the local flare, and FIG. 3 is a graphic chart obtained from the method shown in FIG. 2A to FIG. 2C. Note that, in FIG. 2A to FIG. 2C, a light-shielding region is indicated by being blacked out, and a remaining region is a transmissive region. This is also applicable to the drawings showing the other mask patterns.

In this method, first, with the use of a transmissive line pattern having a width of 0.12 μm as shown in FIG. 2A as a reference, the line width of a pattern formed on the photosensitive body by the transfer of the reference was measured. Subsequently, with the use of a mask provided with a transmissive pattern of an orbicular zone shape around the reference as shown in FIG. 2B, an exposure was performed to measure the line width of a line pattern formed on the photosensitive body. At that time, an inside diameter of a circle was 4.14 μm, and a width of the circle was 2.76 μm. Subsequently, as shown in FIG. 2C, the measurement was similarly made to the line width by varying the inside diameter of the transmissive pattern of the orbicular zone shape while keeping the width of the circle to be constant. At that time, the inside diameter of the circle was 6.89 μm, and the width of the circle was 2.76 μm. Then, the measurements were made for the line width sequentially by varying the inside diameter of the transmissive pattern of the orbicular zone shape while keeping the width of the circle to be constant. Then, variation amounts of respective line widths were plotted in comparison with the line width of the line pattern formed by conducting the exposure using the mask provided with the reference only. FIG. 3 shows the result.

Incidentally, in the exposure, a scanning type exposure apparatus using ArF excimer laser as a light source was used under an illumination condition: numerical aperture NA=0.70 and ½ zone (sigmaout=0.85).

As a result of the above-described quantification, as shown in FIG. 3, a marked increase in the line width arose in an inside diameter range of around 15 μm or below. This indicates that the reference was largely affected by a local flare caused by the pattern distant therefrom at an interval of around 15 μm. Besides, the influence of the local flare came to be larger as the pattern comes close to the reference.

In the present invention, when an irradiation region of a photomask to which at least exposure light is to be applied is sectioned into a plurality of virtual regions having a certain feature size, numerical apertures over the plural virtual regions are substantially uniform. What meant by “numerical apertures are substantially uniform” here is, although the complete uniformity of the numerical apertures is preferable, there is sometimes a case where the numerical apertures cannot be completely uniform due to a constraint on the photomask designing even if a sub-pattern is provided, and the case is also included therein. For instance, the sub-pattern may be formed on the photomask in addition to the main pattern so that those virtual regions exhibiting a lower numerical aperture in aggregate for every pattern except the sub-pattern have lesser amount of reduction in the numerical aperture due to the formation of the sub-patterns.

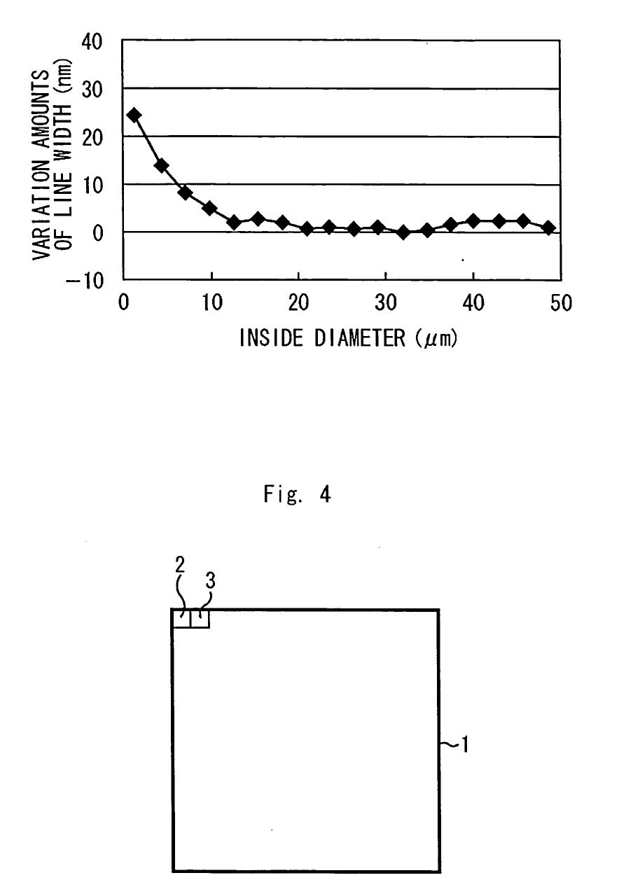

For instance, as shown in FIG. 4, assuming that an irradiation region 1 in the photomask is sectioned into virtual regions of a square each having a side of 2 μm and in the comparison between a virtual region 2 and a virtual region 3 in the drawing, if the aggregate numerical aperture for every pattern except the sub-pattern in the virtual region 2 is lower than that in the virtual region 3, the reduction amount in the numerical aperture caused by the formation of the sub-pattern in the vertical region 2 is higher than the reduction amount in the numerical aperture caused by the formation of the sub-pattern in the vertical region 3. On the other hand, when the aggregate numerical aperture for every pattern except the sub-pattern in the virtual region 3 is lower than that in the virtual region 2, the reduction amount in the numerical aperture caused by the formation of the sub-pattern in the vertical region 2 is lower than the reduction amount in the numerical aperture caused by the formation of the sub-pattern in the vertical region 3. Also, for all of the remaining virtual regions in the irradiation region 1, the reduction amounts in the numerical apertures caused by the formation of the sub-pattern are set as described above, even though it is not shown in FIG. 4. Preferably, the numerical apertures for all of the virtual regions in the irradiation region 1 are uniform.

Here, “an amount of reduction in a numerical aperture” is not an absolute value, and, when the numerical aperture increases caused by the formation of the sub-pattern, a negative value is adopted. Then, the comparison of the reduction amounts is conducted using the negative values as they are.

### Specific Embodiments of the Present Invention

Hereinafter, an embodiment of the present invention will be described based on the drawings.

### First Embodiment

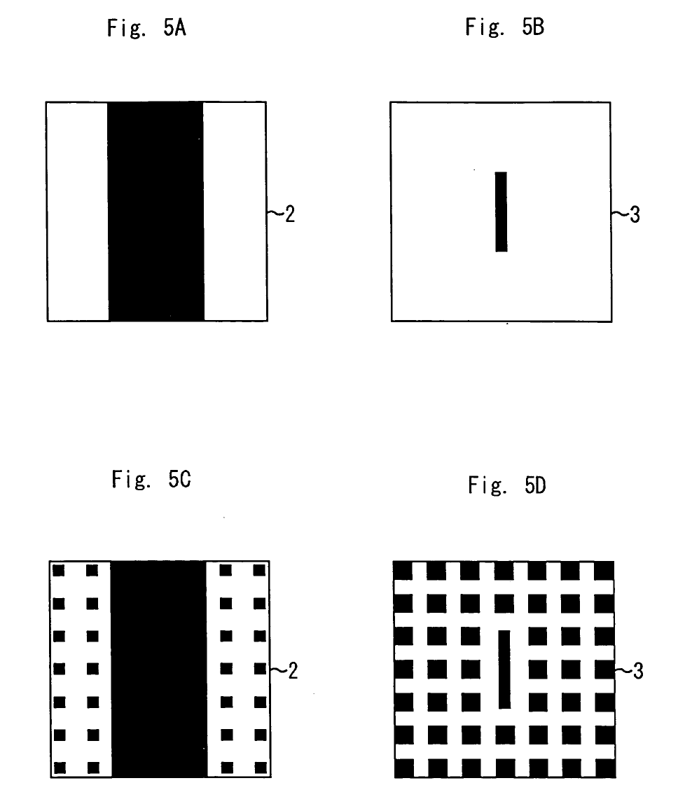

First, a first embodiment according to the present invention will be described. FIG. 5A to FIG. 5D are schematic views showing a photomask according to the first embodiment of the present invention. FIG. 5A shows a main pattern in the virtual region 2 in FIG. 4 and FIG. 5B shows a main pattern in the virtual region 3 in FIG. 4. FIG. 5C shows the main pattern and a sub-pattern (dummy pattern) in the virtual region 2 and FIG. 5D shows the main pattern and a sub-pattern (dummy pattern) in the virtual region 3. These main patterns and sub-patterns are light-shielding patterns.

In the present embodiment, as shown in FIG. 5A and FIG. 5B, if there were formed only the main pattern in each of the virtual regions 2 and 3, the numerical apertures would be 60% and 90%, respectively. Conventional photomasks are used in these states. On the other hand, in the present embodiment, as shown in FIG. 5C and FIG. 5D, dummy patterns are formed to serve as the sub-patterns in the virtual regions 2 and 3. The dummy patterns in the virtual region 2 are square-shaped light shielding patterns each having a side of 0.15 μm, and the dummy patterns in the virtual region 3 are square-shaped light shielding patters each having a side of 0.2 μm. The pitches (center distances) of these dummy patterns are uniform in the virtual regions 2 and 3. The numerical apertures for the virtual regions 2 and 3 are both set to 30%.

Similarly, in all the other virtual regions, dummy patterns of an appropriate size are formed at uniform pitches and the numerical apertures for the respective virtual regions are set to 30%, even though it is not shown in FIG. 5A to FIG. 5D.

In table 1 shown below, “aggregate numerical apertures for every pattern except sub-patterns” and “amount of reduction in numerical apertures caused by formation of sub-patterns” in respective virtual regions are organized and presented.

Here, positions on which the dummy patterns are formed are those positions not affecting an operation of a semiconductor device over an allowable range even if they are transferred to a photosensitive body. In other words, the dummy patterns are formed outside a so-called design data prohibition region (design data prohibition zone). Therefore, a dummy pattern is in no case formed at such a position that causes a short circuit of a wiring or a significant increase in parasitic capacitance.

If an exposure is conducted using the thus-structured photomask according to the first embodiment, in any point in the range of the photosensitive body where exposure light is applied, amounts of light caused by a local flare come to be substantially uniform. As a result, variations in line widths, even if caused, come to be uniform in level over the photomask.

Incidentally, in the first embodiment, the sizes of the dummy patterns are adjusted while fixing the pitches of the dummy patterns to a certain pitch, whereas the numerical apertures over the virtual regions may be uniformed by adjusting the pitches of the dummy patterns while fixing the sizes of the dummy patterns to a certain size. Specifically, the sub-patterns can be formed more sparsely as the numerical aperture for the main pattern lowers. Alternatively, the numerical apertures over the virtual regions may be uniformed by adjusting both the pitches and sizes. In other words, the sub-patterns may be formed in a smaller size and more sparsely as the numerical aperture for the main pattern lowers.

### Second Embodiment

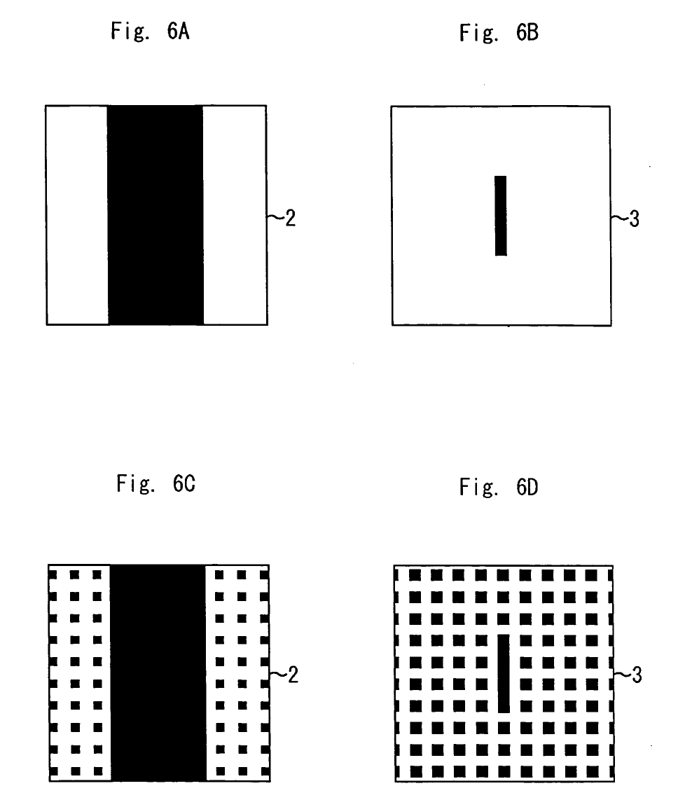

Next, a second embodiment according to the present invention will be described. FIG. 6A to FIG. 6D are schematic views showing a photomask according to the second embodiment of the present invention. FIG. 6A shows a main pattern in the virtual region 2 in FIG. 4, and FIG. 6B shows a main pattern in the virtual region 3 in FIG. 4. Further, FIG. 6C shows the main pattern and a sub-pattern (dummy pattern) in the virtual region 2, and FIG. 6D shows the main pattern and a sub-pattern (dummy pattern) in the virtual region 3. These main patterns and sub-patterns are light-shielding patterns.

Also, in the present embodiment, as shown in FIG. 6A and FIG. 6B, if there were formed only a main pattern in each of the virtual regions 2 and 3, their numerical aperture would be 60% and 90%, respectively. In the present embodiment, further, as shown in FIG. 6C and FIG. 6D, the dummy patterns are formed in the virtual regions 2 and 3 to serve as the sub-patterns. The dummy patterns in the virtual region 2 are square light shielding patterns each having a side of 0.05 μm, and the dummy patterns in the virtual region 3 are square light shielding patterns each having a side of 0.08 μm. The sizes of these dummy patterns are below a resolution limit, so that these dummy patterns are not transferred by exposure. The pitches (center distances) of these dummy patterns are uniform in the virtual regions 2 and 3. The numerical apertures for the virtual regions 2 and 3 are both set to 30%.

Similarly, in all other virtual regions, dummy patterns of an appropriate size are formed at uniform pitches and the numerical apertures for the respective virtual regions are set to 30%, even though it is not shown in FIG. 6A to FIG. 6D.

In table 2 shown below, “aggregate numerical apertures for every pattern except sub-patterns” and “amount of reduction in numerical apertures caused by formation of sub-patterns” in respective virtual regions are organized and presented.

If an exposure is conducted using the thus-structured photomask according to the second embodiment, in any point in the range of the photosensitive body where exposure light is applied, amounts of light caused by a local flare come to be substantially uniform. As a result, variations in line widths, even if caused, come to be uniform in level over the photomask.

Further, in the second embodiment, the respective dummy patterns have sizes smaller than the minimum size of a transferable dummy pattern, so that, differently from the first embodiment, the dummy pattern can be provided even at such a position in a photosensitive body that allows no pattern to be provided.

Incidentally, also in the second embodiment, the sizes of the dummy patterns are adjusted while fixing the pitches of the dummy patterns to a certain pitch, whereas the numerical apertures over the virtual regions may be uniformed by adjusting the pitches of the dummy patterns while fixing the sizes of the dummy patterns to a certain size. Specifically, the sub-patterns can be formed more sparsely as the numerical aperture for the main pattern lowers. Alternatively, the numerical apertures over the virtual regions may be uniformed by adjusting both the pitches and sizes. In other words, the sub-patterns may be formed in a smaller size and more sparsely as the numerical aperture for the main pattern lowers.

### Third Embodiment

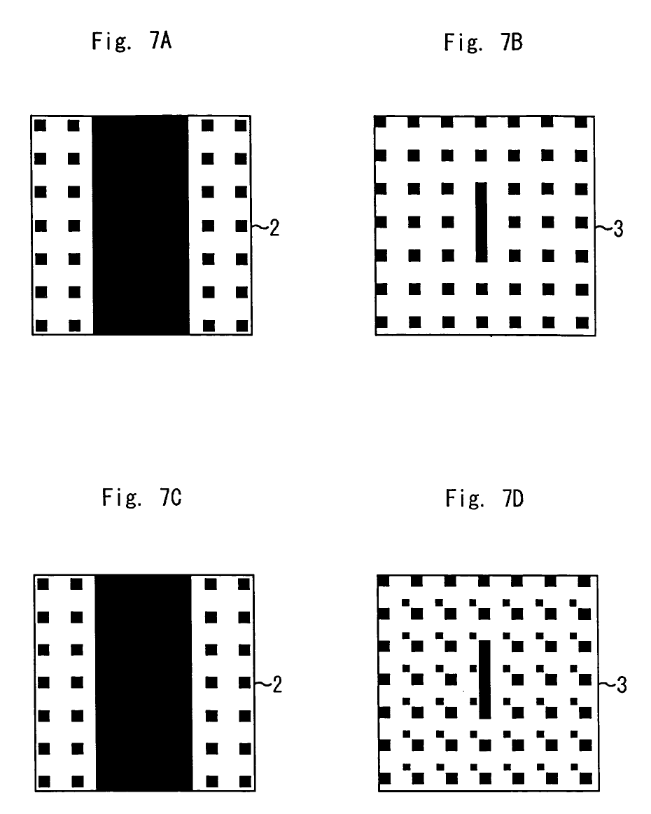

Subsequently, a third embodiment according to the present invention will be described. FIG. 7A to FIG. 7D are schematic views showing a photomask according to the third embodiment of the present invention. FIG. 7A shows a main pattern and a pattern for polishing in the virtual region 2 in FIG. 4, and FIG. 7B shows a main pattern and a pattern for polishing in the virtual region 3 in FIG. 4. Further, FIG. 7C shows the main pattern patterns, the pattern for polishing and a sub-pattern (dummy pattern) in the virtual region 2, and FIG. 7D shows the main pattern, the pattern for polishing, and a sub-pattern (dummy pattern) in the virtual region 3. These main patterns, patterns for polishing, and sub-patterns are light-shielding patterns.

Here, description will be provided for a pattern for polishing. The pattern for polishing has been conventionally formed on the photomask when it is appropriate. In manufacturing a semiconductor device, there may be a case where an etching of a wiring layer, insulating layer or the like on a semiconductor substrate is conducted using a photoresist having a pattern formed thereon as a mask, and thereafter the other materials are filled into a groove or the like formed by the etching, and a planarization process is performed by CMP (Chemical Mechanical Polishing). At that time, if the etched layer in the wafer has large differences in crude density, the polishing amount may vary greatly according to the differences in crude density. Therefore, with the intent to decrease the differences in crude density, sometimes, the patterns for polishing may be provided to have an adequate density on the photomask.

Therefore, in the present embodiment, as shown in FIG. 7A and FIG. 7B, the main pattern and the pattern for polishing are formed on both the virtual regions 2 and 3, and, if there were formed only the main pattern and the pattern for polishing in each of the virtual regions 2 and 3, the numerical apertures would be 30% and 50%, respectively. In the present embodiment, besides, as shown in FIG. 7D, the dummy patterns are also formed on the virtual region 3 to serve as the sub-patterns. The dummy patterns are square light-shielding patterns each having a side of 0.08 μm. The sizes of these dummy patterns are below the resolution limit, so that the patterns are not transferred to the photosensitive body even if exposed. The numerical aperture for the virtual regions 3 is set to 30%. Meanwhile, as shown in FIG. 7C, there is formed no dummy pattern in the virtual region 2, and the numerical aperture stays at 30%.

Further, even though it is not shown in FIG. 7A to FIG. 7D, similarly, in all the other virtual regions, if the numerical aperture is over 30% in the state of having only the main pattern and the pattern for polishing, the dummy pattern of an appropriate size below the resolution limit are formed, and the numerical apertures in the respective regions are set to 30%.

In table 3 shown below, “aggregate numerical apertures for every pattern except sub-patterns” and “amount of reduction in numerical apertures caused by formation of sub-patterns” in respective virtual regions are organized and presented.

If an exposure is conducted using the thus-structured photomask according to the third embodiment, in any point in the range of the photosensitive body where exposure light is applied, amounts of light caused by a local flare come to be substantially uniform. As a result, variations in line widths, even if caused, come to be uniform in level over the photomask.

Further, in the third embodiment, the respective dummy patterns have sizes smaller than the minimum size of a transferable dummy pattern, so that a dummy pattern can be provided even at a position in the photosensitive body where no pattern is allowed to be provided.

### Fourth Embodiment

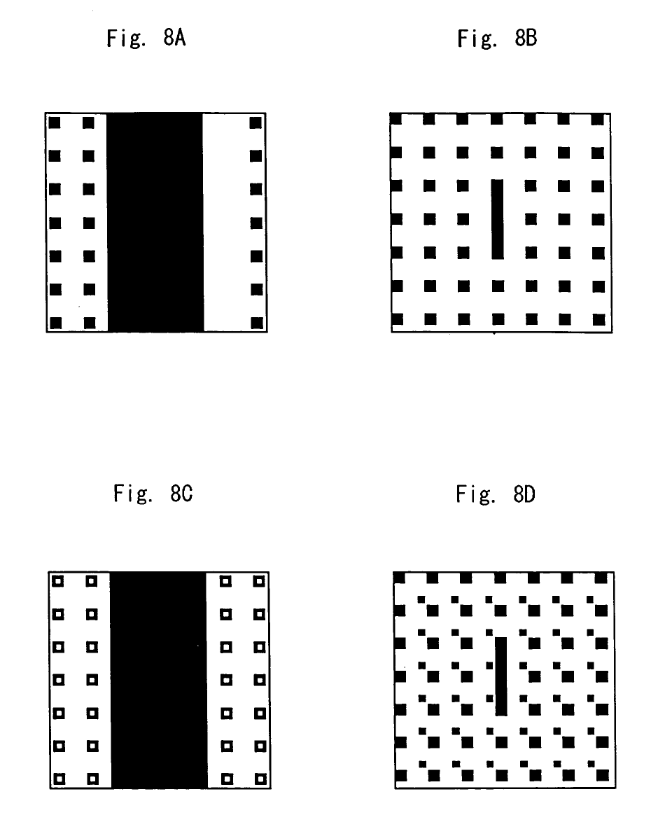

Subsequently, a fourth embodiment according to the present invention will be described. FIG. 8A to FIG. 8D are schematic views showing a photomask according to the fourth embodiment of the present invention. FIG. 8A shows a main pattern and a pattern for polishing in the virtual region 2 in FIG. 4, and FIG. 8B shows a main pattern and a pattern for polishing in the virtual region 3 in FIG. 4. Further, FIG. 8C shows the main pattern, the pattern for polishing and a sub-pattern (dummy pattern) in the virtual region 2, and FIG. 8D shows the main pattern, the pattern for polishing and a sub-pattern (dummy pattern) in the virtual region 3. These main patterns and patterns for polishing are light-shielding patterns, while the sub-patterns include a transmissive pattern in addition to the light-shielding pattern, as will be described herein below.

In the present embodiment, as shown in FIG. 8A and FIG. 8B, the main pattern and pattern for polishing are formed on both the virtual regions 2 and 3, and, if there were formed only the main pattern and the pattern for polishing in each of the virtual regions 2 and 3, the numerical apertures would be 20% and 50%, respectively. In the present embodiment, further, as shown in FIG. 8C, the dummy patterns made of transmissive patterns are formed to serve as the sub-patterns in the virtual region 2. The sizes of these dummy patterns in the virtual region 2 are below a resolution limit, and formed as a hole pattern in the patterns for polishing. Further, as shown in FIG. 8D, dummy patterns are formed in the virtual region 3 to serve as sub-patterns. The respective dummy patterns in the virtual region 3 are square light-shielding patterns each having a side of 0.08 μm. The sizes of these dummy patterns are below the resolution limit, so that the patterns are not transferred to the photosensitive body by exposure. The numerical apertures for the virtual regions 2 and 3 are set to both 30%.

Further, even though it is not shown in FIG. 8A to FIG. 8D, also in all the other virtual regions, if the numerical aperture is over 30% in the state of having only the main pattern and the patterns for polishing, the dummy patterns in an appropriate size below the resolution limit and made of the light-shielding patterns are formed, and if the numerical aperture is below 20% in the state of having only the main pattern and the patterns for polishing, the dummy patterns in an appropriate size below the resolution limit and made of the transmissive patterns are formed in the patterns for polishing. Hence, the numerical apertures are set to 30% in all the regions.

In table 4 shown below, “aggregate numerical apertures for every pattern except sub-patterns” and “amount of reduction in numerical apertures caused by formation of sub-patterns” in respective virtual regions are organized and presented.

If an exposure is conducted using the thus-structured photomask according to the fourth embodiment, in any point in the range of a photosensitive body where an exposure light is applied, amounts of light caused by a local flare come to be substantially uniform. As a result, the variations in line widths, even if caused, come to be uniform in level over the photomask.

According to these embodiments, variations in line width due to an influence by a local flare come to be uniform over the entire photomask. The line width can be increased or decreased with ease for example by adjusting output energy of an exposure apparatus, and so forth. Accordingly, a resist pattern of a desired line width can be obtained with ease without an effort of modifying an intricate pattern on the photomask.

It should be noted that the numerical apertures are assumed to be uniform over the entire virtual regions in these embodiments, whereas, the present invention is not limited thereto. Specifically, even if the numerical apertures are not uniform, it is also within the scope of the present invention that those virtual regions exhibiting a lower numerical aperture in aggregate for every pattern except the sub-pattern have lesser amount of reduction in the numerical aperture due to the formation of the sub-patterns.

The upper limit of the size of the virtual region can be determined based on the range that the local flare affects, and an affecting level. For instance, if a graph shown in FIG. 3 is obtained, it is considered that the influential range of the local flare is within a circle with radius about 20 μm. Meanwhile, as to the lower limit of the size of the virtual region, theologically, the influence of the local flare comes to be uniform as the virtual region becomes smaller, however, if the virtual region is excessively small, there may be a case where the main pattern exists all over the region, leaving no room to provide a sub-pattern. Further, the load on a computer increases as the virtual region becomes small. Accordingly, under a current design rule, the feature of the virtual region is preferably a rectangle having sides from 0.5 μm to 5 μm, in particular, a rectangle having sides from 2 μm to 5 μm.

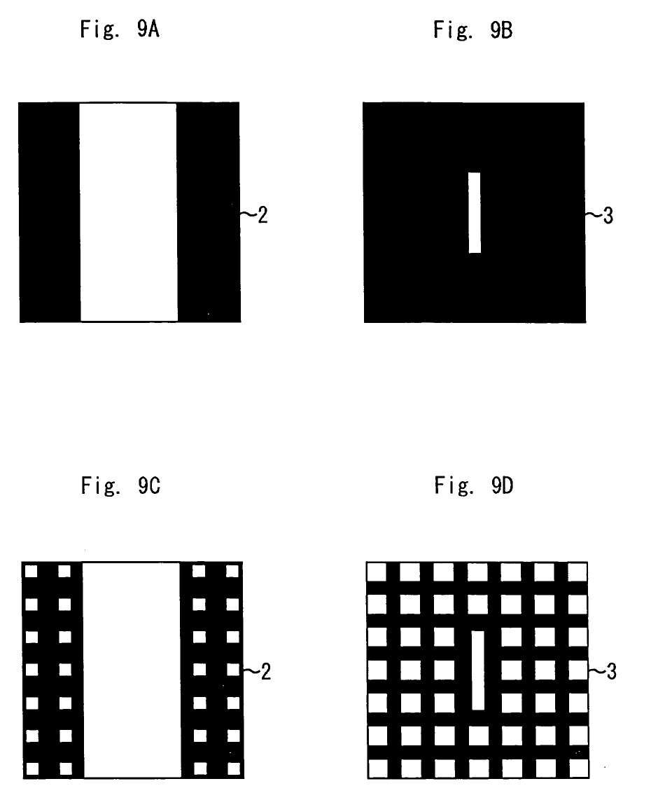

Moreover, in the first to fourth embodiments, a main pattern (and patterns for polishing) is (are) formed as light-shielding pattern(s), whereas, the present invention is also applicable to a photomask in which the main pattern (and the patterns for polishing) is (are) formed as transmissive pattern(s). FIG. 9A to FIG. 9D are schematic views showing a photomask having positive/negative types opposite to the photomask according to the first embodiment. Also, in this case, sub-patterns are formed such that those virtual regions exhibiting a lower numerical aperture in aggregate for every pattern except the sub-pattern have lesser amount of reduction in the numerical aperture due to the formation of the sub-patterns.

In table 5 shown below, “aggregate numerical apertures for every pattern except sub-patterns” and “amount of reduction in numerical apertures caused by formation of sub-patterns” are organized and presented in respective virtual regions.

As shown in Table 5, in the examples shown in FIG. 9A to FIG. 9D, the aggregate numeral apertures of the virtual region 3 for all patterns except sub-patterns (10%) are lower than those of the virtual region 2 (40%), so that the amount of reduction (−60%) in the numeral aperture of the virtual region 3 due to the formation of the sub-patterns is lower than that (−30%) of the virtual region 2.

Subsequently, when designing the aforementioned photomask, a main pattern is determined based on a circuitry, at first. At this time, the designing of patterns for polishing may be made together as in the cases of the third and fourth embodiments. Subsequently, the entire irradiation region is sectioned into virtual regions, and the aggregate numerical aperture for a main pattern (and patterns for polishing), namely the aggregate numerical aperture for all patterns except sub-patterns is obtained for each virtual region. Next, the feature (size) and positions (pitch) of the sub-patterns in the photomask as previously described are determined so that those virtual regions exhibiting a lower numerical aperture in aggregate for every pattern except the sub-pattern have lesser amount of reduction in the numerical aperture due to the formation of the sub-patterns. At this time, such a sub-pattern that is transferred to the photosensitive body may be provided as in the case of the first embodiment, and such a sub-pattern that is not transferred to the photosensitive body may be provided as in the case of the second embodiment. Moreover, the sub-pattern may be provided in the pattern for polishing as in the case of the fourth embodiment. Thus, the patterns for the respective virtual regions are designed to complete the overall designing of the photomask.

Furthermore, what to do when manufacturing a semiconductor device using the aforementioned photomask is, to form a photoresist by a coating or the like beforehand to thereby expose the photoresist using the photomask, to develop the photoresist thereafter, and to process a layer to be processed using the patterned photoresist as a mask.

### INDUSTRIAL APPLICABILITY

As has been described in the above, according to the present invention, in any point in the range of a photosensitive body where an exposure light is applied, amounts of light caused by a local flare is enabled to be substantially uniform. As a result, the variations in line width, even if caused, come to uniform in level over the photomask. Increase or decrease of a line width can be made with ease, for example, by adjusting output energy of an exposure apparatus or the like. Accordingly, a resist pattern of a desired line width can be obtained with ease without an effort of modifying a pattern of an intricate photomask.

TABLE 1

| | Virtual | Virtual |
|---|---|---|
| | region 2 | region 3 |
| Aggregate numerical aperture for | 60% | 90% |
| every pattern except sub- | | |
| patterns | | |
| Amount of reduction in numerical | 30% | 60% |
| apertures caused by formation of | | |
| sub-patterns | | |

TABLE 2

| | Virtual | Virtual |
|---|---|---|
| | region 2 | region 3 |
| Aggregate numerical aperture for | 60% | 90% |
| every pattern except sub- | | |
| patterns | | |
| Amount of reduction in numerical | 30% | 60% |
| apertures caused by formation of | | |
| sub-patterns | | |

TABLE 3

| | Virtual | Virtual |
|---|---|---|
| | region 2 | region 3 |
| Aggregate numerical aperture for | 30% | 50% |
| every pattern except sub- | | |
| patterns | | |
| Amount of reduction in numerical | 0% | 20% |
| apertures caused by formation of | | |
| sub-patterns | | |

TABLE 4

| | Virtual | Virtual |
|---|---|---|
| | region 2 | region 3 |
| Aggregate numerical aperture for | 20% | 50% |
| every pattern except sub- | | |
| patterns | | |
| Amount of reduction in numerical | −10% | 20% |
| apertures caused by formation of | | |
| sub-patterns | | |

TABLE 5

| | Virtual | Virtual |
|---|---|---|
| | region 2 | region 3 |
| Aggregate numerical aperture for | 40% | 10% |
| every pattern except sub- | | |
| patterns | | |
| Amount of reduction in numerical | −30% | −60% |
| apertures caused by formation of | | |
| sub-patterns | | |

1. A photomask having a main pattern which is to be transferred to a photosensitive body formed thereon and used for manufacturing a semiconductor device,
wherein a plurality of sub-patterns are formed optional to be transferred or not to said photosensitive body, and
when an irradiation region to be applied at least exposure light is sectioned into a plurality of virtual regions having a certain feature, numerical apertures are substantially uniform over said plural virtual regions.

2. A photomask having a main pattern which is to be transferred to a photosensitive body formed thereon and used for manufacturing a semiconductor device,
wherein a plurality of sub-patterns are formed optional to be transferred or not to said photosensitive body, and
when an irradiation region to be applied at least exposure light is sectioned into a plurality of virtual regions having a certain feature, of said plural virtual regions, those virtual regions exhibiting a lower numerical aperture in aggregate for every pattern except said sub-pattern have lesser amount of reduction in the numerical aperture due to the formation of said sub-patterns.

3. The photomask according to claim 1, wherein said sub-patterns are formed at positions in an allowable range of affecting an operation of said semiconductor device when said sub-patterns are transferred to said photosensitive body.

4. The photomask according to claim 2, wherein said sub-patterns are formed at positions in an allowable range of affecting an operation of said semiconductor device when said sub-patterns are transferred to said photosensitive body.

5. The photomask according to claim 1, wherein pitches of said sub-patterns are substantially uniform and those virtual regions exhibiting a lower numerical aperture in aggregate for every pattern except said sub-pattern have sub-patterns being smaller in size over the plural virtual regions.

6. The photomask according to claim 2, wherein pitches of said sub-patterns are substantially uniform and those virtual regions exhibiting a lower numerical aperture in aggregate for every pattern except said sub-pattern have sub-patterns being smaller in size over the plural virtual regions.

7. The photomask according to claim 1, wherein the sizes of said sub-patterns are substantially uniform and those virtual regions exhibiting a lower numerical aperture in aggregate for every pattern except said sub-pattern have sub-patterns being formed more sparsely over the plural virtual regions.

8. The photomask according to claim 2, wherein the sizes of said sub-patterns are substantially uniform and those virtual regions exhibiting a lower numerical aperture in aggregate for every pattern except said sub-pattern have sub-patterns being formed more sparsely over the plural virtual regions.

9. The photomask according to claim 1, wherein those virtual regions exhibiting a lower numerical aperture in aggregate for every pattern except said sub-patterns have sub-patterns being smaller in size and formed more sparsely over the plural virtual regions.

10. The photomask according to claim 2, wherein those virtual regions exhibiting a lower numerical aperture in aggregate for every pattern except said sub-patterns have sub-patterns being smaller in size and formed more sparsely over the plural virtual regions.

11. The photomask according to claim 1, wherein said virtual region is a region of a rectangle having respective sides of 0.5 μm to 5 μm.

12. The photomask according to claim 2, wherein said virtual region is a region of a rectangle having respective sides of 0.5 μm to 5 μm.

13. The photomask according to claim 1, wherein the size of said sub-pattern is smaller than a minimum size transferable to said photosensitive body by exposure.

14. The photomask according to claim 2, wherein the size of said sub-pattern is smaller than a minimum size transferable to said photosensitive body by exposure.

15. The photomask according to claim 1, wherein a pattern for polishing is formed, said pattern for polishing being larger than a minimum size transferable to said photosensitive body by exposure and being in an allowable range of affecting an operation of said semiconductor device when said pattern for polishing is transferred to said photosensitive body.

16. The photomask according to claim 2, wherein a pattern for polishing is formed, said pattern for polishing being larger than a minimum size transferable to said photosensitive body by exposure and being in an allowable range of affecting an operation of said semiconductor device when said pattern for polishing is transferred to said photosensitive body.

17. The photomask according to claim 15, wherein,
said sub-pattern and said pattern for polishing are of either a positive type or a negative type being different from each other, and
said sub-pattern is formed inside said pattern for polishing.

18. The photomask according to claim 16, wherein,
said sub-pattern and said pattern for polishing are of either a positive type or a negative type being different from each other, and
said sub-pattern is formed inside said pattern for polishing.

19. A designing method of a photomask having a main pattern which is to be transferred to a photosensitive body formed thereon and used for manufacturing a semiconductor device, said designing method comprising the steps of:
determining a main pattern based on a circuitry of said semiconductor device;
sectioning an irradiation region to be applied at least exposure light into a plurality of virtual regions of a certain optional feature and calculating an aggregate numerical aperture for the patterns determined at that time for each virtual region; and
determining a plurality of sub-patterns being optional to be transferred or not to said photosensitive body, in said step of determining a plurality of sub-patterns, the numerical apertures being made to be substantially uniform over the plural virtual regions.

20. A designing method of a photomask having a main pattern which is to be transferred to a photosensitive body formed thereon and used for manufacturing a semiconductor device, said designing method comprising the steps of:
determining a main pattern based on a circuitry of said semiconductor device;
sectioning an irradiation region to be applied at least exposure light into a plurality of virtual regions of a certain optional feature and calculating an aggregate numerical aperture for the patterns determined at that time for each virtual region; and
determining a plurality of sub-patterns being optional to be transferred or not to said photosensitive body, in said step of determining a plurality of sub-patterns, those virtual regions exhibiting a lower numerical aperture in aggregate for every pattern except said sub-pattern having lesser amount of reduction in the numerical aperture due to formation of said sub-patterns.

21. The designing method of a photomask according to claim 19, wherein, in said step of determining a plurality of sub-patterns, said plurality of sub-patterns are arranged at positions in an allowable range of affecting an operation of said semiconductor device when said sub-patterns are transferred to said photosensitive body.

22. The designing method of a photomask according to claim 20, wherein, in said step of determining a plurality of sub-patterns, said plurality of sub-patterns are arranged at positions in an allowable range of affecting an operation of said semiconductor device when said sub-patterns are transferred to said photosensitive body.

23. The designing method of a photomask according to claim 19, wherein, in said step of determining a plurality of sub-patterns, pitches of said sub-patterns are substantially uniform over the plural virtual regions, and those virtual regions exhibiting a lower numerical aperture in aggregate for every pattern except said sub-pattern have sub-patterns being smaller in size.

24. The designing method of a photomask according to claim 20, wherein, in said step of determining a plurality of sub-patterns, pitches of said sub-patterns are substantially uniform over the plural virtual regions, and those virtual regions exhibiting a lower numerical aperture in aggregate for every pattern except said sub-pattern have sub-patterns being smaller in size.

25. The designing method of a photomask according to claim 19, wherein, in said step of determining a plurality of sub-patterns, sizes of said sub-patterns are substantially uniform over the plural virtual regions, and those virtual regions exhibiting a lower numerical aperture in aggregate for every pattern except said sub-pattern have sub-patterns being arranged more sparsely.

26. The designing method of a photomask according to claim 20, wherein, in said step of determining a plurality of sub-patterns, sizes of said sub-patterns are substantially uniform over the plural virtual regions, and those virtual regions exhibiting a lower numerical aperture in aggregate for every pattern except said sub-pattern have sub-patterns being arranged more sparsely.

27. The designing method of a photomask according to claim 19, wherein, in said step of determining a plurality of sub-patterns, those virtual regions exhibiting a lower numerical aperture in aggregate for every pattern except said sub-pattern have sub-patterns being smaller in size and arranged more sparsely.

28. The designing method of a photomask according to claim 20, wherein, in said step of determining a plurality of sub-patterns, those virtual regions exhibiting a lower numerical aperture in aggregate for every pattern except said sub-pattern have sub-patterns being smaller in size and arranged more sparsely.

29. The designing method of a photomask according to claim 19, wherein, in said step of determining a plurality of sub-patterns, said virtual region is made to be a rectangle having respective sides of 0.5 μm to 5 μm.

30. The designing method of a photomask according to claim 20, wherein, in said step of determining a plurality of sub-patterns, said virtual region is made to be a rectangle having respective sides of 0.5 μm to 5 μm.

31. The designing method of a photomask according to claim 19, wherein, in said step of determining a plurality of sub-patterns, said sub-pattern has a size smaller than a minimum size transferable to said photosensitive body by exposure.

32. The designing method of a photomask according to claim 20, wherein, in said step of determining a plurality of sub-patterns, said sub-pattern has a size smaller than a minimum size transferable to said photosensitive body by exposure.

33. The designing method of a photomask according to claim 19,
further comprising the step of determining a pattern for polishing, before said step of calculating the aggregate numerical aperture, said pattern for polishing being larger than a minimum size transferable to said photosensitive body by exposure and being in an allowable range of affecting an operation of said semiconductor device when said pattern is transferred to said photosensitive body.

34. The designing method of a photomask according to claim 20,
further comprising the step of determining a pattern for polishing, before said step of calculating the aggregate numerical aperture, said pattern for polishing being larger than a minimum size transferable to said photosensitive body by exposure and being in an allowable range of affecting an operation of said semiconductor device when said pattern is transferred to said photosensitive body.

35. The designing method of a photomask according to claim 33, wherein
said sub-pattern and said pattern for polishing are of either a positive type or a negative type being different from each other, and
said sub-pattern is formed inside said pattern for polishing.

36. The designing method of a photomask according to claim 34, wherein
said sub-pattern and said pattern for polishing are of either a positive type or a negative type being different from each other, and
said sub-pattern is formed inside said pattern for polishing.

37. A semiconductor device manufacturing method comprising the step of exposing a photosensitive body formed on a layer to be processed using a photomask described in claim 1.

38. A semiconductor device manufacturing method comprising the step of exposing a photosensitive body formed on a layer to be processed using a photomask described in claim 2.
